(19) United States
(12) Patent Application Publication
(10) Pub. No.: US 2025/0320381 A1
(43) Pub. Date: Oct. 16, 2025

(54) POLISHING COMPOSITION, POLISHING METHOD, AND METHOD FOR MANUFACTURING SEMICONDUCTOR SUBSTRATE

(71) Applicant: FUJIMI INCORPORATED, Kiyosu-shi (JP)

(72) Inventors: Ryota MAE, Kiyosu-shi (JP); Akane KUMAYAMA, Kiyosu-shi (JP); Noriyuki TANAKA, Kiyosu-shi (JP); Masaki TADA, Kiyosu-shi (JP)

(73) Assignee: FUJIMI INCORPORATED, Kiyosu-shi (JP)

(21) Appl. No.: 19/060,023

(22) Filed: Feb. 21, 2025

(30) Foreign Application Priority Data
Mar. 11, 2024 (JP) 2024-036949
Sep. 11, 2024 (JP) 2024-157358

(51) Int. Cl. C09G 1/02

(52) U.S. Cl. CPC C09G 1/02

(57) ABSTRACT

The present disclosure provides a means capable of reducing scratches on a surface of a polished object to be polished (particularly, silicon oxide). The present disclosure is a polishing composition containing abrasive grains, an inorganic salt, an organic onium salt, in which the organic onium salt contains at least one of a tetraalkylammonium salt represented by Chemical Formula 1 below or a tetraalkylphosphonium salt represented by Chemical Formula 2 below, and a zeta potential of the abrasive grains in the polishing composition is negative:

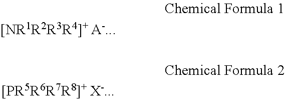

in the Chemical Formula 1 and the Chemical Formula 2,
R¹ to R⁸ each independently represent an unsubstituted alkyl group having 1 or more and 4 or less carbon atoms, and
A⁻ and X⁻ each independently represent a monovalent anion.

### BACKGROUND

### 1. Technical Field

The present disclosure relates to a polishing composition, a polishing method, and a method for manufacturing a semiconductor substrate.

### 2. Description of Related Arts

In recent years, in accordance with multilayer wiring on a surface of a semiconductor substrate, when manufacturing a device, semiconductor substrates are physically polished and planarized, that is, so-called chemical mechanical polishing (CMP) technology is utilized. CMP is a method of planarizing a surface of an object to be polished such as a semiconductor substrate using a polishing composition (slurry) containing abrasive grains such as silica, alumina, and ceria, an anticorrosive agent, a surfactant, and the like, and the object to be polished (target to be polished) is silicon, polysilicon, silicon oxide (SiO₂), carbon-containing silicon oxide (SiOC) and silicon nitride (SiN), wiring and plug made of metal, and the like.

For example, JP-A-2016-56292 discloses a polishing composition which contains abrasive grains and at least one of polyacrylic acid and a polyacrylic acid derivative, and in which an electrical conductivity is 2.0 mS/cm or more. According to JP-A-2016-56292, silicon oxide can be polished at a high polishing removal rate.

### SUMMARY

However, the technique described in JP-A-2016-56292 still has room for improvement in terms of reducing scratches on the surface of the polished object to be polished.

Therefore, an object of the present disclosure is to provide a means capable of reducing scratches on the surface of a polished object to be polished (particularly, silicon oxide).

The inventors of the present disclosure have conducted intensive studies which may solve the above problems. As a result, the inventors of the present disclosure have found that the above problems may be solved by a polishing composition containing abrasive grains, an inorganic salt, and an organic onium salt, in which the organic onium salt contains at least one of a tetraalkylammonium salt represented by the following Chemical Formula 1 or a tetraalkylphosphonium salt represented by the following Chemical Formula 2, and a zeta potential of the abrasive grains in the polishing composition is negative, and have completed the invention of the present disclosure.

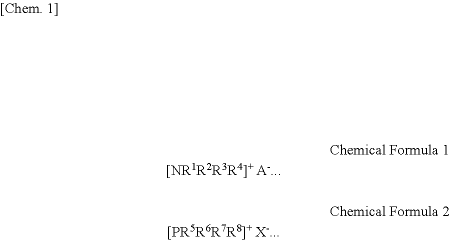

In the above Chemical Formula 1 and Chemical Formula 2,
R¹ to R⁸ each independently represent an unsubstituted alkyl group having 1 or more and 4 or less carbon atoms, and
A⁻ and X⁻ each independently represent a monovalent anion.

### DETAILED DESCRIPTION

According to an embodiment of the present disclosure, there is provided a polishing composition containing abrasive grains, an inorganic salt, and an organic onium salt, in which the organic onium salt contains at least one of a tetraalkylammonium salt represented by the following Chemical Formula 1 or a tetraalkylphosphonium salt represented by the following Chemical Formula 2, and a zeta potential of the abrasive grains in the polishing composition is negative.

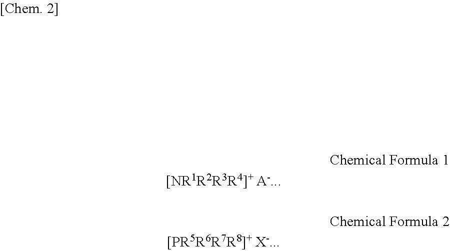

In the above Chemical Formula 1 and Chemical Formula 2,
R¹ to R⁸ each independently represent an unsubstituted alkyl group having 1 or more and 4 or less carbon atoms, and
A⁻ and X⁻ each independently represent a monovalent anion.

According to such a polishing composition of the present disclosure, scratches on the surface of the polished object to be polished (particularly, silicon oxide) can be reduced.

Hereinafter, embodiments of the present disclosure will be described in detail, but the present disclosure is not limited only to the following embodiments, and various modifications can be made within the scope of claims. The embodiments described in the present specification may be other embodiments by being combined in any manner. In the present specification, unless otherwise specified, operations and measurements of physical properties and the like are performed under conditions of room temperature (20° C. or more and 25° C. or less)/relative humidity of 40% RH or more and 50% RH or less.

In the present specification, “X or more and Y or less” is used to mean that numerical values (X and Y) described before and after the “X or more and Y or less” are included as a lower limit value and an upper limit value. In a case where a plurality of terms “X or more and Y or less” are described, for example, in a case where “X1 or more and Y1 or less, or X2 or more and Y2 or less” is described, a disclosure with each numerical value as an upper limit, a disclosure with each numerical value as a lower limit, and a combination of the upper limit and the lower limit are all disclosed (that is, these are lawful basis for amendment). Specifically, all of the amendment to X1 or more, the amendment to Y2 or less, the amendment to X1 or less, the amendment to Y2 or more, the amendment to X1 or more and X2 or less, the amendment to X1 or more and Y2 or less, and the like must all be deemed lawful.

### [Abrasive Grains]

The polishing composition according to the present disclosure contains abrasive grains. The abrasive grains have an action of mechanically polishing the object to be polished, and improve the polishing removal rate of the object to be polished by the polishing composition.

In the polishing composition of the present disclosure, the abrasive grains have a negative zeta potential. Here, the “zeta (ζ) potential” is a potential difference generated at an interface between a solid and a liquid in contact with each other when the solid and the liquid perform relative movement. When the zeta potential of the abrasive grains is 0 mV or positive, scratches on the surface of the polished object to be polished increase.

The zeta potential of the abrasive grains in the polishing composition of the present disclosure is preferably −60 mV or more and −10 m V or less, more preferably −50 mV or more and −10 mV or less, still more preferably −40 mV or more and −15 mV or less, and particularly preferably more than −35 mV and −15 mV or less. Since the abrasive grains have a zeta potential in such a range, the polishing removal rate of the object to be polished can be further improved. Here, the zeta potential of the abrasive grains in the polishing composition is a value measured by the method described in Examples. In addition, the zeta potential of the abrasive grains can be adjusted by the amount of an anionic group (particularly, an organic acid group) of the abrasive grains described below, the pH of the polishing composition, and the like.

The type of abrasive grain is not particularly limited, and examples thereof include metal oxides such as silica, alumina, zirconia, and titania. The abrasive grains can be used alone or in combination of two or more types thereof. As the abrasive grains, a commercially available product or a synthetic product may be used.

The type of abrasive grain is preferably silica, and more preferably colloidal silica. Examples of the method for manufacturing colloidal silica include a sodium silicate method and a sol-gel method, and any colloidal silica manufactured by any manufacturing method is suitably used as the abrasive grains according to the present disclosure. However, from the viewpoint of reducing metal impurities, colloidal silica manufactured by a sol-gel method, which can manufacture colloidal silica with high purity, is preferable.

The manufacturing of colloidal silica by the sol-gel method can be performed using a conventionally known method, and specifically, colloidal silica can be obtained by performing a hydrolysis/condensation reaction using a hydrolyzable silicon compound (for example, an alkoxysilane or a derivative thereof) as a raw material.

In some embodiments of the present disclosure, the colloidal silica contained in the polishing composition is preferably anionically modified colloidal silica (anion-modified colloidal silica), and more preferably colloidal silica with an organic acid immobilized on the surface. Colloidal silica with an organic acid immobilized on the surface tends to have a larger absolute value of zeta potential in the polishing composition than normal colloidal silica with no organic acid immobilized thereon. Therefore, it is easy to adjust the zeta potential of the colloidal silica in the polishing composition to negative (for example, in the range of −40 mV or more and −15 mV or less).

Preferable examples of the colloidal silica with an organic acid immobilized on the surface include colloidal silica with an organic acid group such as a carboxylic acid group, a sulfonic acid group, a phosphonic acid group, or an aluminate group immobilized on the surface. Among them, from the viewpoint of easy manufacturing, colloidal silica with sulfonic acid and carboxylic acid immobilized on the surface is preferable, and colloidal silica with sulfonic acid immobilized on the surface is more preferable.

The immobilization of the organic acid on the surface of the colloidal silica is not achieved by simply allowing the colloidal silica and the organic acid to be present together. For example, when a sulfonic acid, which is a type of organic acid, is immobilized on colloidal silica, the immobilization can be performed by, for example, the method described in “Sulfonic acid-functionalized silica through quantitative oxidation of thiol groups”, Chem. Commun. 246-247 (2003). Specifically, a silane coupling agent having a thiol group such as 3-mercaptopropyltrimethoxysilane is coupled to colloidal silica, and then the thiol group is oxidized with hydrogen peroxide, whereby colloidal silica (sulfonic acid-modified colloidal silica) with sulfonic acid immobilized on the surface can be obtained.

Alternatively, when a carboxylic acid, which is a type of organic acid, is immobilized on colloidal silica, the immobilization can be performed, for example, by the method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, a silane coupling agent containing a photoreactive 2-nitrobenzyl ester is coupled to colloidal silica and then irradiated with light, whereby colloidal silica (carboxylic acid-modified colloidal silica) with a carboxylic acid immobilized on the surface can be obtained.

The shape of the abrasive grains is not particularly limited, and may be spherical or non-spherical. Specific examples of the non-spherical shape include various shapes such as a polygonal columnar shape such as a triangular prism and a quadrangular prism, a columnar shape, a barrel shape in which the central portion of the cylinder bulges more than the end portions, a donut shape in which a central portion of a disk penetrates, a plate shape, a so-called cocoon shape having a constriction at the central portion, a so-called associated spherical shape in which a plurality of particles are integrated, a so-called Konpeito shape having a plurality of protrusions, and a rugby ball shape, and are not particularly limited.

The size of the abrasive grains is not particularly limited. For example, the average primary particle size of the abrasive grains is preferably 5 nm or more, more preferably 8 nm or more, still more preferably 10 nm or more, and particularly preferably 12 nm or more. As the average primary particle size of the abrasive grains increases, the polishing removal rate of the object to be polished by the polishing composition is improved. In addition, the average primary particle size of the abrasive grains is preferably 100 nm or less, more preferably 80 nm or less, still more preferably 60 nm or less, and particularly preferably 50 nm or less. As the average primary particle size of the abrasive grains decreases, it becomes easier to obtain a surface with fewer defects by polishing using the polishing composition. That is, the average primary particle size of the abrasive grains is preferably 5 nm or more and 100 nm or less, more preferably 8 nm or more and 80 nm or less, still more preferably 10 nm or more and 60 nm or less, and particularly preferably 12 nm or more and 50 nm or less. The average primary particle size of the abrasive grains can be calculated based on, for example, the specific surface area (SA) of the abrasive grains calculated from the BET method on the assumption that the shape of the abrasive grains is a true sphere. In the present specification, as the average primary particle size of the abrasive grains, a value measured by the method described in Examples is adopted.

In addition, the average secondary particle size of the abrasive grains is preferably 10 nm or more, more preferably 15 nm or more, still more preferably 20 nm or more, and particularly preferably 25 nm or more. As the average secondary particle size of the abrasive grains increases, resistance during polishing decreases, and polishing can be stably performed. In addition, the average secondary particle size of the abrasive grains is preferably 400 nm or less, more preferably 300 nm or less, still more preferably 200 nm or less, and particularly preferably 100 nm or less. As the average secondary particle size of the abrasive grains decreases, the surface area per unit mass of the abrasive grains increases, the contact frequency with the object to be polished is improved, and the polishing removal rate is further improved. That is, the average secondary particle size of the abrasive grains is preferably 10 nm or more and 400 nm or less, more preferably 15 nm or more and 300 nm or less, still more preferably 20 nm or more and 200 nm or less, and particularly preferably 25 nm or more and 100 nm or less. The average secondary particle size of the abrasive grains can be measured by, for example, a dynamic light scattering method represented by a laser diffraction scattering method.

The average association degree of the abrasive grains is preferably 5.0 or less, more preferably 4.0 or less, still more preferably 3.0 or less, and particularly preferably 2.5 or less. As the average association degree of the abrasive grains decreases, defects can be further reduced. The average association degree of the abrasive grains is preferably 1.0 or more, more preferably 1.5 or more, and still more preferably 2.0 or more. The average association degree is obtained by dividing the value of the average secondary particle size of the abrasive grains by the value of the average primary particle size. As the average association degree of the abrasive grains increases, there is an advantageous effect that the polishing removal rate of the object to be polished by the polishing composition is improved.

The upper limit of the aspect ratio of the abrasive grains in the polishing composition is not particularly limited, but is preferably less than 2.0, more preferably 1.8 or less, and still more preferably 1.5 or less. Within such a range, defects on the surface of the object to be polished can be further reduced. The aspect ratio is an average of values obtained by taking the smallest rectangle circumscribing the image of the abrasive grains by the scanning electron microscope and dividing the length of the long side of the rectangle by the length of the short side of the same rectangle, and can be obtained using general image analysis software. The lower limit of the aspect ratio of the abrasive grains in the polishing composition is not particularly limited, but is preferably 1.0 or more, and more preferably 1.2 or more.

In the particle size distribution of the abrasive grains determined by a laser diffraction scattering method, the lower limit of D90/D10, which is the ratio between the particle size (D90) when the integrated particle mass reaches 90% of the total particle mass from the fine particle side and the particle size (D10) when the total particle mass reaches 10% of the total particle mass, is not particularly limited, but is preferably 1.1 or more, more preferably 1.4 or more, still more preferably 1.7 or more, and most preferably 2.0 or more. In addition, in the particle size distribution of the abrasive grains in the polishing composition determined by a laser diffraction scattering method, the upper limit of the ratio D90/D10 of the particle size (D90) when the integrated particle mass reaches 90% of the total particle mass from the fine particle side to the particle size (D10) when the total particle mass reaches 10% of the total particle mass is not particularly limited, but is preferably 3.0 or less, and more preferably 2.5 or less. Within such a range, defects on the surface of the object to be polished can be further reduced.

The size (average primary particle size, average secondary particle size, aspect ratio, D90/D10, and the like) of the abrasive grains can be appropriately controlled by selecting a method for manufacturing the abrasive grains, for example.

The concentration (content) of the abrasive grains is not particularly limited, but is preferably 0.5% by mass or more, more preferably 0.8% by mass or more, still more preferably 1% by mass or more, further preferably more than 1% by mass, and particularly preferably 1.5% by mass or more, with respect to the total mass of the polishing composition. In addition, the upper limit of the concentration (content) of the abrasive grains is preferably 20% by mass or less, more preferably 15% by mass or less, still more preferably 10% by mass or less, and particularly preferably 5% by mass or less, with respect to the total mass of the polishing composition. That is, the concentration (content) of the abrasive grains is preferably 0.5% by mass or more and 20% by mass or less, more preferably 0.8% by mass or more and 20% by mass or less, still more preferably 1% by mass or more and 15% by mass or less, still more preferably more than 1% by mass and 10% by mass or less, and particularly preferably 1.5% by mass or more and 5% by mass or less, with respect to the total mass of the polishing composition. Within such a range, the polishing removal rate can be improved while suppressing the cost. In addition, in a case where the polishing composition contains two or more types of abrasive grains, the concentration (content) of the abrasive grains means the total amount thereof.

### [Inorganic Salt]

The polishing composition according to the present disclosure contains an inorganic salt. The inorganic salt has a function of reducing scratches on the surface of the polished object to be polished (particularly, silicon oxide). In addition, the inorganic salt has a function of increasing the electrical conductivity of the polishing composition to further improve the polishing removal rate of the object to be polished (particularly, silicon oxide).

Examples of the inorganic salt include inorganic salts composed of a cation and an anion shown below. Examples of the cation include alkali metal ions such as lithium ions, sodium ions, and potassium ions, alkaline earth metal ions such as magnesium ions, calcium ions, and strontium ions, polyatomic ions such as ammonium ions, complex ions, and the like. Examples of the anion include a halide ion (fluoride ion, chloride ion, bromide ion, iodide ion, and the like), an oxoacid ion (a borate ion, a carbonate ion, a nitrate ion, a nitrite ion, a metasilicate ion, a phosphate ion, a monohydrogen phosphate ion, a dihydrogen phosphate ion, a phosphonate ion, a monohydrogen phosphonate ion, a phosphinate ion, a sulfate ion, a sulfonate ion, a sulfite ion, a thiosulfate ion, a chromate ion, a dichromate ion, a permanganate ion, and the like), a thiocyanate ion, a cyanate ion, a sulfamate ion, and the like.

More specific examples of the inorganic salt include lithium salts such as lithium chloride, lithium bromide, lithium carbonate, lithium nitrate, and lithium thiocyanate; calcium salts such as calcium chloride, calcium bromide, calcium carbonate, calcium nitrate and calcium thiocyanate; iron salts such as iron nitrate and iron thiocyanate; potassium salts such as potassium chloride, potassium bromide, potassium nitrate, potassium sulfate, potassium thiocyanate, potassium sulfamate, potassium phosphate, potassium dihydrogen phosphate, potassium monohydrogen phosphate, and potassium monohydrogen phosphonate; sodium salts such as sodium chloride, sodium bromide, sodium nitrate, sodium sulfate, and sodium thiocyanate; zinc salts such as zinc chloride, zinc nitrate, and zinc thiocyanate; magnesium salts such as magnesium nitrate, magnesium sulfate, and magnesium thiocyanate; strontium salts such as strontium nitrate and strontium thiocyanate; and ammonium salts such as ammonium chloride, ammonium bromide, ammonium iodide, ammonium nitrate, ammonium phosphate, ammonium dihydrogen phosphate, ammonium monohydrogen phosphate, ammonium phosphonate, ammonium monohydrogen phosphonate, ammonium sulfate, ammonium thiocyanate, ammonium sulfamate, and the like. These inorganic salts may be used alone or in combination of two or more types thereof. As the inorganic salt, a commercially available product may be used, or a synthetic product may be used.

Among them, it is preferable to contain at least one of an ammonium salt of an inorganic acid or a potassium salt of an inorganic acid from the viewpoint of further exhibiting the effect of the present disclosure. The inorganic acid is preferably sulfuric acid, nitric acid, or carbonic acid. Therefore, the inorganic salt is more preferably at least one selected from the group consisting of ammonium sulfate, ammonium nitrate, ammonium carbonate, potassium sulfate, potassium nitrate, or potassium carbonate, or still more preferably ammonium sulfate.

The concentration (content) of the inorganic salt in the polishing composition is not particularly limited, but in the case of a polishing composition used for polishing an object to be polished as it is as a polishing liquid, the lower limit of the concentration (content) of the inorganic salt in the polishing composition is preferably 0.005% by mass (50 ppm by mass) or more, and may be 0.01% by mass (100 ppm by mass) or more, 0.1% by mass (1,000 ppm by mass) or more, 0.2% by mass (2,000 ppm by mass) or more, or 0.5% by mass (5,000 ppm by mass) or more, with respect to the total mass of the polishing composition. In addition, the upper limit of the concentration (content) of the inorganic salt in the polishing composition is preferably 2.0% by mass (20,000 ppm by mass) or less, and may be 1.5% by mass (15,000 ppm by mass) or less, 1.3% by mass (13,000 ppm by mass) or less, 1.0% by mass (10,000 ppm by mass) or less, or 0.9% by mass (9,000 ppm by mass) or less, with respect to the total mass of the polishing composition.

That is, the concentration (content) of the inorganic salt is preferably 0.005% by mass (50 ppm by mass) or more and 2.0% by mass (20,000 ppm by mass) or less, and may be 0.01% by mass (100 ppm by mass) or more and 1.5% by mass (15,000 ppm by mass) or less, 0.1% by mass (1,000 ppm by mass) or more and 1.3% by mass (13,000 ppm by mass) or less, 0.2% by mass (2,000 ppm by mass) or more and 1.0% by mass (10,000 ppm by mass) or less, 0.2% by mass (2,000 ppm by mass) or more and 0.9% by mass (9,000 ppm by mass) or less, 0.5% by mass (5,000 ppm by mass) or more and 1.0% by mass (10,000 ppm by mass) or less, or 0.5% by mass (5,000 ppm by mass) or more and 0.9% by mass (9,000 ppm by mass) or less, with respect to the total mass of the polishing composition.

When the polishing composition contains two or more types of inorganic salts, the concentration (content) of the inorganic salts means the total amount thereof.

### [Organic Onium Salt]

The polishing composition according to the present disclosure contains an organic onium salt. The organic onium salt has a function of reducing scratches on the surface of the polished object to be polished (particularly, silicon oxide).

The organic onium salt used in the present disclosure includes at least one of a tetraalkylammonium salt represented by the following Chemical Formula 1 or a tetraalkylphosphonium salt represented by the following Chemical Formula 2.

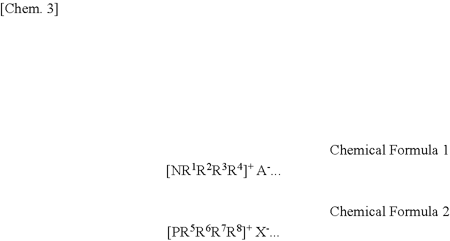

In the above Chemical Formula 1 and Chemical Formula 2,
R¹ to R⁸ each independently represent an unsubstituted alkyl group having 1 or more and 4 or less carbon atoms, and
A⁻ and X⁻ each independently represent a monovalent anion.

When an organic onium salt having an alkyl group having 5 or more carbon atoms is used, scratches on the surface of the polished object to be polished increase.

Specific examples of the unsubstituted alkyl group having 1 or more and 4 or less carbon atoms used for R¹ to R⁸ in the above Chemical Formulas 1 and 2 include a methyl group, an ethyl group, a n-propyl group, an isopropyl group, an n-butyl group, a sec-butyl group, an isobutyl group, and a tert-butyl group. From the viewpoint that the effect of the present disclosure is further exhibited, an unsubstituted alkyl group having 2 or more and 4 or less carbon atoms, such as an ethyl group, an n-propyl group, an isopropyl group, an n-butyl group, a sec-butyl group, an isobutyl group, and a tert-butyl group, is preferable.

Examples of the monovalent anion used for A⁻ and X⁻ in the above Chemical Formulas 1 and 2 are not particularly limited, but are halide ions such as a fluoride ion, a chloride ion, a bromide ion, and an iodide ion; hydroxide ion; organic acid ions such as benzoate ions are suitable; and the like. The monovalent anion may be used alone or in combination of two or more types thereof. From the viewpoint that the effect of the present disclosure is more exhibited, A⁻ and X⁻ in the above Chemical Formulas 1 and 2 are preferably hydroxide ions (OH).

More specific examples of the tetraalkylammonium salt represented by the above Chemical Formula 1 include tetramethylammonium fluoride, trimethylethylammonium fluoride, dimethyldiethylammonium fluoride, methyltriethylammonium fluoride, tetraethylammonium fluoride, trimethyl n-propylammonium fluoride, trimethylisopropylammonium fluoride, dimethylethyl n-propylammonium fluoride, dimethylethyl isopropylammonium fluoride, methyl diethyl n-propylammonium fluoride, methyl diethylisopropylammonium fluoride, triethyl isopropylammonium fluoride, triethyl n-propylammonium fluoride, tetra n-propylammonium fluoride, tetraisopropylammonium fluoride, tetra n-butylammonium fluoride, and tetra tert-butylammonium fluoride; tetramethylammonium chloride, trimethylethylammonium chloride, dimethyldiethylammonium chloride, methyltriethylammonium chloride, tetraethylammonium chloride, trimethyl n-propylammonium chloride, trimethylisopropylammonium chloride, dimethylethyl n-propylammonium chloride, dimethylethylisopropylammonium chloride, methyldiethyl n-propylammonium chloride, methyldiethylisopropylammonium chloride, triethylisopropylammonium chloride, triethyl n-propylammonium chloride, tetra n-propylammonium chloride, tetraisopropylammonium chloride, tetra n-butylammonium chloride, and tetra tert-butylammonium chloride; tetramethylammonium bromide, trimethylethylammonium bromide, dimethyldiethylammonium bromide, methyltriethylammonium bromide, tetraethylammonium bromide, trimethyl n-propylammonium bromide, trimethylisopropylammonium bromide, dimethylethyl n-propylammonium bromide, dimethylethylisopropylammonium bromide, methyldiethyl n-propylammonium bromide, methyldiethylisopropylammonium bromide, triethylisopropylammonium bromide, triethyl n-propylammonium bromide, tetra n-propylammonium bromide, tetraisopropylammonium bromide, tetra n-butylammonium bromide, and tetra tert-butylammonium bromide; tetramethylammonium iodide, trimethylethylammonium iodide, dimethyldiethylammonium iodide, methyltriethylammonium iodide, tetraethylammonium iodide, trimethyl n-propylammonium iodide, trimethylisopropylammonium iodide, dimethylethyl n-propylammonium iodide, dimethylethylisopropylammonium iodide, methyldiethyl n-propylammonium iodide, methyldiethylisopropylammonium iodide, triethylisopropylammonium iodide, triethyl n-propylammonium iodide, tetra n-propylammonium iodide, tetraisopropylammonium iodide, tetra n-butylammonium iodide, and tetra tert-butylammonium iodide; tetramethylammonium hydroxide, trimethylethylammonium hydroxide, dimethyldiethylammonium hydroxide, n-methyltriethylammonium hydroxide, tetraethylammonium hydroxide, trimethyl propylammonium hydroxide, trimethylisopropylammonium hydroxide, dimethylethyl n-propylammonium hydroxide, dimethylethylisopropylammonium hydroxide, methyldiethyl n-methyldiethylisopropylammonium hydroxide, propylammonium hydroxide, triethylisopropylammonium hydroxide, triethyl n-propylammonium hydroxide, tetra n-propylammonium hydroxide, tetraisopropylammonium hydroxide, tetra n-butylammonium hydroxide, and tetra tert-butylammonium hydroxide; and tetramethylammonium benzoate, trimethylethylammonium benzoate, dimethyldiethylammonium benzoate, methyltriethylammonium benzoate, tetraethylammonium benzoate, trimethyl n-propylammonium benzoate, trimethylisopropylammonium benzoate, dimethylethyl n-propylammonium benzoate, dimethylethylisopropylammonium benzoate, methyldiethyl n-propylammonium benzoate, methyldiethylisopropylammonium benzoate, triethylisopropylammonium benzoate, triethyl n-propylammonium benzoate, tetra n-propylammonium benzoate, tetraisopropylammonium benzoate, tetra n-butylammonium benzoate, tetra tert-butylammonium benzoate, and the like.

More specific examples of the tetraalkylphosphonium salt represented by the above Chemical Formula 2 include tetramethylphosphonium fluoride, trimethylethylphosphonium fluoride, dimethyldiethylphosphonium fluoride, methyltriethylphosphonium fluoride, tetraethylphosphonium fluoride, trimethyl n-propylphosphonium fluoride, trimethylisopropylphosphonium fluoride, dimethylethyl n-propylphosphonium fluoride, dimethylethylisopropylphosphonium fluoride, methyldiethyl n-propylphosphonium fluoride, methyldiethylisopropylphosphonium fluoride, triethylisopropylphosphonium fluoride, triethyl n-propylphosphonium fluoride, tetra n-propylphosphonium fluoride, tetraisopropylphosphonium fluoride, tetra n-butylphosphonium fluoride, and tetra tert-butylphosphonium fluoride; trimethylethylphosphonium chloride, tetramethylphosphonium chloride, dimethyldiethylphosphonium chloride, methyltriethylphosphonium chloride, tetraethylphosphonium chloride, trimethyl n-propylphosphonium chloride, trimethylisopropylphosphonium chloride, dimethylethyl n-propylphosphonium chloride, dimethylethylisopropylphosphonium chloride, methyldiethyl n-propylphosphonium chloride, methyldiethylisopropylphosphonium chloride, triethylisopropylphosphonium chloride, triethyl n-propylphosphonium chloride, tetra n-propylphosphonium chloride, tetraisopropylphosphonium chloride, tetra n-butylphosphonium chloride, and tetra tert-butylphosphonium chloride; bromide, tetramethylphosphonium bromide, trimethylethylphosphonium dimethyldiethylphosphonium bromide, methyltriethylphosphonium bromide, tetraethylphosphonium bromide, trimethyl n-propylphosphonium bromide, trimethylisopropylphosphonium bromide, dimethylethyl n-propylphosphonium bromide, dimethylethylisopropylphosphonium bromide, methyldiethyl n-propylphosphonium bromide, methyldiethylisopropylphosphonium bromide, triethylisopropylphosphonium bromide, triethyl n-propylphosphonium bromide, tetra n-propylphosphonium bromide, tetraisopropylphosphonium bromide, tetra n-butylphosphonium bromide, and tetra tert-butylphosphonium bromide; tetramethylphosphonium iodide, trimethylethylphosphonium iodide, dimethyldiethylphosphonium iodide, methyltriethylphosphonium iodide, tetraethylphosphonium iodide, trimethyl n-propylphosphonium iodide, trimethylisopropylphosphonium iodide, dimethylethyl n-propylphosphonium dimethylethylisopropylphosphonium iodide, iodide, methyldiethyl n-propylphosphonium iodide, methyldiethylisopropylphosphonium triethylisopropylphosphonium iodide, triethyl n-propylphosphonium iodide, tetra n-propylphosphonium iodide, tetraisopropylphosphonium iodide, tetra n-butylphosphonium iodide, and tetra tert-butylphosphonium iodide; tetramethylphosphonium hydroxide, trimethylethylphosphonium hydroxide, dimethyldiethylphosphonium hydroxide, methyltriethylphosphonium hydroxide, tetraethylphosphonium hydroxide, trimethyl n-propylphosphonium hydroxide, trimethylisopropylphosphonium hydroxide, dimethylethyl n-propylphosphonium hydroxide, dimethylethyl isopropylphosphonium hydroxide, methyldiethyl n-propylphosphonium hydroxide, methyldiethylisopropylphosphonium hydroxide, triethyl isopropylphosphonium hydroxide, triethyl isopropylphosphonium hydroxide, triethyl n-propylphosphonium hydroxide, tetra n-propylphosphonium hydroxide, tetraisopropylphosphonium hydroxide, tetra n-butylphosphonium hydroxide, and tetra tert-butylphosphonium hydroxide; and tetramethyl phosphonium benzoate, trimethylethyl phosphonium benzoate, dimethyl diethyl phosphonium benzoate, methyl triethyl phosphonium benzoate, tetraethyl phosphonium benzoate, trimethyl n-propyl phosphonium benzoate, trimethylisopropyl phosphonium benzoate, dimethylethyl n-propyl phosphonium benzoate, dimethylethyl isopropyl phosphonium benzoate, methyl diethyl n-propyl phosphonium benzoate, methyl diethyl isopropyl phosphonium benzoate, triethyl isopropyl phosphonium benzoate, triethyl n-propyl phosphonium benzoate, tetra n-propyl phosphonium benzoate, tetraisopropyl phosphonium benzoate, tetra n-butyl phosphonium benzoate, tetra tert-butyl ammonium benzoate, and the like.

These organic onium salts may be used alone or in combination of two or more types thereof. In addition, as the organic onium salt, a commercially available product or a synthetic product may be used.

Among these organic onium salts, a tetraalkylammonium salt represented by the above Chemical Formula 1 is preferable, and at least one selected from the group consisting of tetraethylammonium hydroxide, tetrapropylammonium hydroxide, or tetra n-butylammonium hydroxide is more preferable from the viewpoint of more easily exhibiting the effect of the present disclosure.

The lower limit of the concentration (content) of the organic onium salt in the polishing composition is preferably 0.001% by mass (10 ppm by mass) or more, and may be 0.0013% by mass (13 ppm by mass) or more, 0.0015% by mass (15 ppm by mass) or more, 0.002% by mass (20 ppm by mass) or more, 0.0025% by mass (25 ppm by mass) or more, 0.005% by mass (50 ppm by mass) or more, 0.007% by mass (70 ppm by mass) or more, or 0.01% by mass (100 ppm by mass) or more, with respect to the total mass of the polishing composition. In addition, the upper limit of the concentration (content) of the organic onium salt in the polishing composition is preferably 0.3% by mass (3,000 ppm by mass) or less, and may be 0.1% by mass (1,000 ppm by mass) or less, 0.07% by mass (700 ppm by mass) or less, 0.05% by mass (500 ppm by mass) or less, 0.04% by mass (400 ppm by mass) or less, 0.03% by mass (300 ppm by mass) or less, 0.02% by mass (200 ppm by mass) or less, 0.01% by mass (100 ppm by mass) or less, 0.008% by mass (80 ppm by mass or less) or 0.005% by mass (50 ppm by mass) or less, with respect to the total mass of the polishing composition.

That is, the concentration (content) of the organic onium salt in the polishing composition is preferably 0.001% by mass (10 ppm by mass) or more and 0.3% by mass (3,000 ppm by mass) or less, and may be 0.005% by mass (50 ppm by mass) or more and 0.1% by mass (1,000 ppm by mass) or less, 0.007% by mass (70 ppm by mass) or more and 0.07% by mass (700 ppm by mass) or less, or 0.01% by mass (100 ppm by mass) or more and 0.05% by mass (500 ppm by mass) or less, with respect to the total mass of the polishing composition. Alternatively, from the viewpoint of further reducing scratches on the surface of the polished object to be polished, the concentration (content) of the organic onium salt in the polishing composition may be 0.001% by mass (10 ppm by mass) or more and 0.01% by mass (100 ppm by mass) or less, 0.0013% by mass (13 ppm by mass) or more and 0.01% by mass (100 ppm by mass) or less, 0.0015% by mass (15 ppm by mass) or more and 0.008% by mass (80 ppm by mass) or less, 0.002% by mass (20 ppm by mass) or more and 0.008% by mass (80 ppm by mass) or less, or 0.0025% by mass (25 ppm by mass) or more and 0.005% by mass (50 ppm by mass) or less, with respect to the total mass of the polishing composition.

When the polishing composition contains two or more types of organic onium salts, the concentration (content) of the organic onium salt means the total amount thereof.

### [pH and pH Adjusting Agent]

The pH of the polishing composition according to the present disclosure is not particularly limited, but is preferably 1.0 or more, more preferably 1.5 or more, and still more preferably 2.0 or more. In addition, the pH is preferably 9.0 or less, more preferably 7.0 or less, still more preferably less than 7.0, further preferably 5.0 or less, and particularly preferably 3.5 or less. That is, the pH of the polishing composition according to the present disclosure is preferably 1.0 or more and 9.0 or less, more preferably 1.5 or more and 7.0 or less, still more preferably 1.5 or more and less than 7.0, further preferably 1.5 or more and 5.0 or less, and particularly preferably 2.0 or more and 3.5 or less.

The inorganic salt and the organic onium salt contained in the polishing composition according to the present disclosure may have a role as a pH adjusting agent for adjusting the pH of the polishing composition, but may further contain a separate pH adjusting agent depending on the target pH. Such a pH adjusting agent may be either an acid or a base, or may be either an inorganic compound or an organic compound. The pH adjusting agent can be used alone or in combination of two or more types thereof.

Specific examples of the acid that can be used as the pH adjusting agent include inorganic acids such as hydrochloric acid, sulfuric acid, nitric acid, hydrofluoric acid, boric acid, carbonic acid, hypophosphorous acid, phosphorous acid, and phosphoric acid; organic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic acid, and phenoxyacetic acid.

Examples of the base that can be used as the pH adjusting agent include amines such as aliphatic amines and aromatic amines, hydroxides of alkali metals such as sodium hydroxide and potassium hydroxide, hydroxides of Group 2 elements, ammonia, and the like.

The addition amount of the pH adjusting agent is not particularly limited, and may be appropriately adjusted such that the polishing composition has the desired pH. In addition, the pH of the polishing composition can be measured by, for example, a pH meter, and specifically, can be measured by the method described in Examples.

### [Dispersing Medium]

The polishing composition according to the present disclosure preferably further contains a dispersing medium. As the dispersing medium, water; alcohols such as methanol, ethanol, and ethylene glycol; ketones such as acetone or the like; and mixtures thereof; and the like can be exemplified. Among these, water is preferable as the dispersing medium. That is, according to a preferred aspect of the present disclosure, the dispersing medium contains water. According to a more preferred aspect of the present disclosure, the dispersing medium is substantially composed of water. Note that the above “substantially” is intended to mean that a dispersing medium other than water can be contained as long as the object of the present disclosure can be achieved, and more specifically, the dispersing medium is preferably composed of 90% by mass or more and 100% by mass or less of water and 0% by mass or more and 10% by mass or less of a dispersing medium other than water, and more preferably composed of 99% by mass or more and 100% by mass or less of water and 0% by mass or more and 1% by mass or less of a dispersing medium other than water. Most preferably, the dispersing medium is water.

From the viewpoint of preventing the action of the components contained in the polishing composition from being inhibited, water that does not contain impurities as much as possible is preferable as the dispersing medium, and specifically, pure water, ultrapure water, or distilled water from which impurity ions are removed with an ion exchange resin and then foreign substances are removed through a filter is more preferable.

### [Electrical Conductivity of Polishing Composition]

The electrical conductivity (EC) of the polishing composition according to the present disclosure is not particularly limited, but is preferably 1 mS/cm or more, and more preferably 2 mS/cm or more. In addition, the electrical conductivity (EC) of the polishing composition according to the present disclosure is preferably 25 mS/cm or less, and more preferably 20 mS/cm or less. That is, the electrical conductivity (EC) of the polishing composition according to the present disclosure is preferably 1 mS/cm or more and 25 mS/cm or less, and more preferably 2 mS/cm or more and 20 mS/cm or less. When the electrical conductivity (EC) of the polishing composition is in such a range, repulsion between the abrasive grains can be appropriately adjusted, and stability can be secured. The electrical conductivity of the polishing composition can be adjusted by the type, amount and the like of a pH adjusting agent or the like. In addition, the electrical conductivity can be measured by the method described in Examples.

### [Other Components]

The polishing composition according to the present disclosure may further contain other components such as a water-soluble polymer, a complexing agent, a metal anticorrosive, an antiseptic agent, an antifungal agent, a reducing agent, and a surfactant, as necessary. Hereinafter, an antiseptic agent and an antifungal agent which are preferable components will be described. The oxidizing agent will also be described.

### (Water-Soluble Polymer)

The polishing composition according to the present disclosure preferably further contains a water-soluble polymer. The water-soluble polymer is easily adsorbed on the surface of the object to be polished and has a role of protecting the surface of the object to be polished. As a result, in a case where polishing is performed using a polishing composition containing a water-soluble polymer, the number of scratches on the surface of the polished object to be polished can be further reduced.

The water-soluble polymer referred to herein is a water-soluble polymer having the same repeating structural unit (homopolymer), or a water-soluble polymer having different repeating units (copolymer), and can typically be a compound having a weight average molecular weight (Mw) of 100 or more. The type of polymer used as the water-soluble polymer is not particularly limited, and any of anionic, cationic, nonionic, and amphoteric polymers can be used. When the water-soluble polymer is a copolymer, the form of the copolymer may be any of a block copolymer, a random copolymer, a graft copolymer, an alternating copolymer, and a periodic copolymer.

Examples of the anionic water-soluble polymer include polyvinylsulfonic acid, polystyrenesulfonic acid, polyallylsulfonic acid, polymethallylsulfonic acid, poly(2-acrylamide-2-methylpropanesulfonic acid), polyisoprenesulfonic acid, polyacrylic acid, polymethacrylic acid, and the like.

Examples of the cationic water-soluble polymer include polyethyleneimine (PEI), polyvinylamine, polyallylamine, polyvinylpyridine, a polymer of cationic acrylamide, and the like. As a specific example of the polyallylamine, for example, polydiallyldimethylammonium chloride or the like can be used.

Examples of the nonionic water-soluble polymer include polyvinyl alcohol, an ethylene-vinyl alcohol copolymer, polyvinyl pyrrolidone, polyacrylamide, poly N-vinylacetamide, a polyamine compound, a polyvinyl ether compound (polyvinyl methyl ether, polyvinyl ethyl ether, polyvinyl isobutyl ether, and the like), a polyoxyalkylene compound (polyethylene glycol (polyethylene oxide), polypropylene glycol (polypropylene oxide), polytrimethylene glycol (polytrimethylene oxide), polybutylene glycol (polybutylene oxide), and the like), polyglycerin, and polysaccharides such as water-soluble cellulose (hydroxyethyl cellulose (HEC), hydroxypropyl cellulose, hydroxyethyl methyl cellulose, hydroxypropyl methyl cellulose, methyl cellulose, ethyl cellulose, and ethyl hydroxyethyl cellulose), alginic acid polyhydric alcohol esters, water-soluble urea resins, dextrin derivatives, casein, and the like. In addition, not only those having such a main chain structure but also a graft copolymer having a nonionic polymer structure in a side chain can be suitably used.

Examples of the amphoteric water-soluble polymer include a copolymer of a vinyl monomer having an anionic group and a vinyl monomer having a cationic group, and a vinyl-based amphoteric polymer having a carboxybetaine group, a sulfobetaine group, or the like, and specifically include an acrylic acid/dimethylaminoethyl methacrylic acid copolymer, an acrylic acid/diethylaminoethyl methacrylic acid copolymer, and the like.

Furthermore, the copolymer of a water-soluble polymer exemplified above can also be used.

The water-soluble polymer may be used alone or in combination of two or more types thereof. As the water-soluble polymer, a commercially available product or a synthetic product may be used.

Among these water-soluble polymers, it is preferable to contain a nonionic water-soluble polymer from the viewpoint of further reducing scratches on the surface of the polished object to be polished (particularly, silicon oxide). More preferably, the water-soluble polymer contains polyvinyl alcohol. More preferably, the water-soluble polymer contains polyvinyl alcohol and a polyoxyalkylene compound. In addition, the polyoxyalkylene compound preferably contains at least one of polyethylene glycol or polypropylene glycol.

The weight average molecular weight (Mw) of the water-soluble polymer can be appropriately set depending on the type of the water-soluble polymer. In general, the lower limit of the weight average molecular weight (Mw) of the water-soluble polymer is preferably 100 or more, and may be 200 or more, 300 or more, 400 or more, 500 or more, 600 or more, 800 or more, 1,000 or more, 1,500 or more, 2,000 or more, 3,000 or more, 4,000 or more, or 5,000 or more. The upper limit of the weight average molecular weight (Mw) of the water-soluble polymer is preferably 500,000 or less, and may be 100,000 or less, 50,000 or less, 30,000 or less, 20,000 or less, 10,000 or less, 8,000 or less, 5,000 or less, 3,000 or less, 2,000 or less, 1,000 or less, or 800 or less.

As an example, the weight average molecular weight (Mw) of the water-soluble polymer may be 1,000 or more and 100,000 or less, 1,500 or more and 50,000 or less, 2,000 or more and 20,000 or less, 3,000 or more and 20,000 or less, or 5,000 or more and 20,000 or less. As another example, the weight average molecular weight (Mw) of the water-soluble polymer may be 100 or more and 2,000 or less, 200 or more and 2,000 or less, 200 or more and 1,000 or less, or 300 or more and 800 or less.

For example, in a case where the water-soluble polymer is polyvinyl alcohol, the lower limit of the weight average molecular weight (Mw) of the polyvinyl alcohol may be 1,000 or more, 1,500 or more, 2,000 or more, 3,000 or more, or 5,000 or more. The upper limit of the weight average molecular weight (Mw) of the polyvinyl alcohol may be 100,000 or less, 50,000 or less, or 20,000 or less. That is, the weight average molecular weight (Mw) of the polyvinyl alcohol may be 1,000 or more and 100,000 or less, 1,500 or more and 50,000 or less, 2,000 or more and 20,000 or less, 3,000 or more and 20,000 or less, or 5,000 or more and 20,000 or less.

For example, in a case where the water-soluble polymer is a polyoxyalkylene compound, the lower limit of the weight average molecular weight (Mw) of the polyoxyalkylene compound may be 100 or more, 200 or more, or 300 or more. The upper limit of the weight average molecular weight (Mw) of the polyoxyalkylene compound may be 2,000 or less, 1,000 or less, or 800 or less. That is, the weight average molecular weight (Mw) of the polyoxyalkylene compound may be 100 or more and 2,000 or less, 200 or more and 2,000 or less, 200 or more and 1,000 or less, or 300 or more and 800 or less.

The weight average molecular weight (Mw) of the water-soluble polymer can be measured as a value in terms of polyethylene glycol using gel permeation chromatography (GPC).

The concentration (content) of the water-soluble polymer in the polishing composition is appropriately set according to the type of the water-soluble polymer to be used. In general, the lower limit of the concentration (content) of the water-soluble polymer is preferably 0.01% by mass (100 ppm by mass) or more, and may be 0.02% by mass (200 ppm by mass) or more, 0.03% by mass (300 ppm by mass) or more, 0.04% by mass (400 ppm by mass) or more, 0.05% by mass (500 ppm by mass) or more, 0.06% by mass (600 ppm by mass) or more, 0.07% by mass (700 ppm by mass) or more, 0.08% by mass (800 ppm by mass) or more, 0.09% by mass (900 ppm by mass) or more, or 0.1% by mass (1,000 ppm by mass) or more, with respect to the total mass of the polishing composition. In addition, the upper limit of the concentration (content) of the water-soluble polymer in the polishing composition is preferably 1% by mass (10,000 ppm by mass) or less, and may be 0.9% by mass (9,000 ppm by mass) or less, 0.8% by mass (8,000 ppm by mass) or less, 0.7% by mass (7,000 ppm by mass) or less, 0.6% by mass (6,000 ppm by mass) or less, 0.5% by mass (5,000 ppm by mass) or less, 0.4% by mass (4,000 ppm by mass) or less, 0.3% by mass (3,000 ppm by mass) or less, or 0.2% by mass (2,000 ppm by mass) or less, with respect to the total mass of the polishing composition.

That is, the concentration (content) of the water-soluble polymer in the polishing composition is preferably 0.01% by mass (100 ppm by mass) or more and 1% by mass (10,000 ppm by mass) or less, and may be 0.02% by mass (200 ppm by mass) or more and 0.9% by mass (9,000 ppm by mass) or less, 0.03% by mass (300 ppm by mass) or more and 0.8% by mass (8,000 ppm by mass) or less, 0.04% by mass (400 ppm by mass) or more and 0.7% by mass (7,000 ppm by mass) or less, 0.05% by mass (500 ppm by mass) or more and 0.6% by mass (6,000 ppm by mass) or less, 0.06% by mass (600 ppm by mass) or more and 0.5% by mass (5,000 ppm by mass) or less, 0.07% by mass (700 ppm by mass) or more and 0.4% by mass (4,000 ppm by mass) or less, 0.08% by mass (800 ppm by mass) or more and 0.3% by mass (3,000 ppm by mass) or less, 0.09% by mass (900 ppm by mass) or more and 0.3% by mass (3,000 ppm by mass) or less, or 0.1% by mass (1,000 ppm by mass) or more and 0.2% by mass (2,000 ppm by mass) or less, with respect to the total mass of the polishing composition.

In a case where the polishing composition contains two or more types of water-soluble polymers, the content of the water-soluble polymers is intended to be the total amount thereof.

### (Antiseptic Agent and Antifungal Agent)

Examples of the antiseptic agent and the antifungal agent that can be added to the polishing composition according to the present disclosure include isothiazoline-based antiseptic agents such as 2-methyl-4-isothiazoline-3-one and 5-chloro-2-methyl-4-isothiazoline-3-one, paraoxybenzoic acid esters, phenoxyethanol, and the like. These antiseptic agents and the antifungal agents may be used alone, or may be used in combination of two or more thereof.

### (Oxidizing Agent)

The polishing composition according to the present disclosure preferably does not substantially contain an oxidizing agent. When the polishing composition contains an oxidizing agent, the surface of the object to be polished is oxidized to generate an oxide film, and there is a concern that the polishing time becomes long. Specific examples of the oxidizing agent herein include hydrogen peroxide (H₂O₂), sodium persulfate, ammonium persulfate, sodium dichloroisocyanurate, and the like. The fact that the polishing composition does not substantially contain an oxidizing agent means that the polishing composition does not at least intentionally contain an oxidizing agent. Therefore, a polishing composition inevitably containing a trace amount of an oxidizing agent derived from a raw material, a production method, or the like is included in the concept of the polishing composition that does not substantially contain an oxidizing agent. For example, the concentration (content) of the oxidizing agent in the polishing composition is preferably 0.01% by mass (100 ppm by mass) or less, more preferably less than 0.01% by mass (100 ppm by mass), and still more preferably 0.005% by mass (50 ppm by mass) or less. The lower limit of the concentration (content) of the oxidizing agent is preferably 0% by mass or more, and more preferably 0.0005% by mass (5 ppm by mass) or more.

### [Form of Polishing Composition]

The polishing composition according to the present disclosure is typically supplied to an object to be polished in the form of a polishing liquid containing the polishing composition, and is used for polishing the object to be polished. The polishing composition according to the present disclosure may be, for example, diluted (typically diluted with water) and used as a polishing liquid, or may be used as it is as a polishing liquid. That is, the concept of the polishing composition according to the present disclosure includes both a polishing composition (working slurry) supplied to an object to be polished and used for polishing the object to be polished and a concentrated solution (stock solution of working slurry) diluted and used for polishing. The concentration ratio of the concentrated solution can be, for example, about 2 times or more and 100 times or less on a volume basis, and usually about 3 times or more and 50 times or less is appropriate.

### [Object to be Polished]

The object to be polished according to the present disclosure is not particularly limited, and examples thereof include single crystal silicon, polycrystalline silicon (polysilicon), polycrystalline silicon doped with an n-type or p-type impurity, non-crystal silicon (amorphous silicon), amorphous silicon doped with an n-type or p-type impurity, silicon oxide, silicon nitride, silicon carbonitride (SiCN), a metal, SiGe, a carbon-containing material, and the like.

Examples of the object to be polished containing silicon oxide include a TEOS type silicon oxide film (hereinafter also simply referred to as “TEOS film”) generated using tetraethyl orthosilicate as a precursor, a high density plasma (HDP) film, an undoped silicate glass (USG) film, a phosphorus silicate glass (PSG) film, a boron-phospho silicate glass (BPSG) film, a rapid thermal oxidation (RTO) film, and the like.

Examples of the metal include tungsten, copper, aluminum, cobalt, hafnium, nickel, gold, silver, platinum, palladium, rhodium, ruthenium, iridium, osmium, and the like.

Examples of the carbon-containing material include amorphous carbon, spin-on carbon (SOC), diamond-like carbon (DLC), nanocrystalline diamond, graphene, and the like.

The object to be polished may be a commercially available product or may be manufactured by a known method.

Among them, an object to be polished containing silicon oxide is preferable. Therefore, according to a preferred embodiment of the present disclosure, the polishing composition is used for polishing an object to be polished containing silicon oxide.

### [Method for Manufacturing Polishing Composition]

The method for manufacturing the polishing composition according to the present embodiment is not particularly limited, and for example, the polishing composition can be obtained by stirring and mixing abrasive grains, an inorganic salt, an organic onium salt, and other additives added as necessary. Details of each component are as described above.

The temperature at which each component is mixed is not particularly limited, but is preferably 10° C. or more and 40° C. or less, and heating may be performed in order to increase the rate of dissolution. The mixing time is also not particularly limited as long as the mixture can be uniformly mixed.

### [Polishing Method and Method for Manufacturing Semiconductor Substrate]

As described above, the polishing composition according to the present embodiment is particularly suitably used for polishing an object to be polished containing silicon oxide. Therefore, the present disclosure provides a polishing method for polishing an object to be polished containing silicon oxide with the polishing composition according to the present embodiment. In addition, the present disclosure also provides a method for manufacturing a semiconductor substrate, the method including polishing a semiconductor substrate containing silicon oxide by the polishing method according to the polishing method.

As the polishing apparatus, it is possible to use a general polishing apparatus in which a holder for holding a substrate or the like having an object to be polished, a motor capable of changing the rotation speed, or the like are attached, and which has a polishing table to which a polishing pad (polishing cloth) can be attached.

As the polishing pad, a general nonwoven fabric, polyurethane, a porous fluororesin, and the like can be used without particular limitation. The polishing pad is preferably grooved such that a polishing liquid is accumulated.

Regarding the polishing conditions, for example, the rotation speed of the polishing table (platen) and the carrier (head) is preferably 10 rpm (0.17 s⁻¹) or more and 500 rpm (8.33 s⁻¹) or less. The pressure (polishing pressure) applied to the substrate having the object to be polished is preferably 0.5 psi (3.45 kPa) or more and 10 psi (68.9 kPa) or less.

The method for supplying the polishing composition to the polishing pad is not particularly limited, and for example, a method for continuously supplying the polishing composition by a pump or the like is adopted. This supply amount is not limited, but it is preferable that the surface of the polishing pad is covered with the polishing composition according to the present disclosure.

The polishing composition according to the present disclosure may be a single-component type or a multi-component type including a two-component type. In addition, the polishing composition according to the present disclosure may be prepared by diluting a stock solution of the polishing composition with a diluent such as water to, for example, 2 times or more and 100 times or less, usually 3 times or more and 50 times or less on a volume basis.

### [Number of Scratches]

As described above, the polishing composition according to the present disclosure can reduce scratches on the surface of the polished object to be polished.

In the present disclosure, the number of scratches on the surface of the polished object to be polished is preferably as small as possible. Specifically, the number of scratches is practically 25 or less, preferably 20 or less, more preferably 15 or less, still more preferably 10 or less, and particularly preferably less than 10. In the present specification, as the number of scratches, a value measured by the method described in Examples is adopted.

Although the embodiments of the present disclosure have been described in detail, this is illustrative and exemplary and not restrictive, and it is clear that the scope of the present disclosure should be interpreted by the appended claims.

The present disclosure includes the following aspects and embodiments:

1. A polishing composition containing
abrasive grains, an inorganic salt, an organic onium salt, in which
the organic onium salt contains at least one of a tetraalkylammonium salt represented by Chemical Formula 1 below or a tetraalkylphosphonium salt represented by Chemical Formula 2 below, and
a zeta potential of the abrasive grains in the polishing composition is negative,

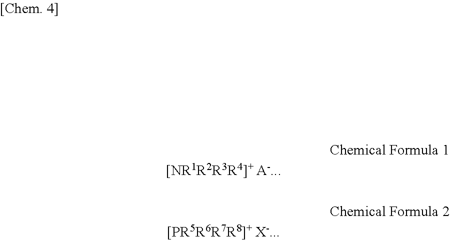

in the Chemical Formula 1 and the Chemical Formula 2,
R¹ to R⁸ each independently represent an unsubstituted alkyl group having 1 or more and 4 or less carbon atoms, and
A⁻ and X⁻ each independently represent a monovalent anion;

2. The polishing composition according to the above 1., in which the inorganic salt contains at least one selected from the group consisting of ammonium sulfate, ammonium nitrate, ammonium carbonate, potassium sulfate, potassium nitrate, or potassium carbonate;

3. The polishing composition according to the above 1, or 2., in which the organic onium salt is a tetraalkylammonium salt represented by the Chemical Formula 1;

4. The polishing composition according to any one of the above 1. to 3., in which A⁻ and X⁻ in the Chemical Formula 1 and the Chemical Formula 2 are hydroxide ions;

5. The polishing composition according to any one of the above 1. to 4., in which the tetraalkylammonium salt represented by the Chemical Formula 1 contains at least one selected from the group consisting of tetraethylammonium hydroxide, tetrapropylammonium hydroxide, or tetra n-butylammonium hydroxide;

6. The polishing composition according to any one of the above 1. to 5., in which a concentration of the organic onium salt with respect to a total mass of the polishing composition is 0.001% by mass or more and 0.01% by mass or less;

7. The polishing composition according to any one of the above 1. to 6., in which pH is less than 7.0;

8. The polishing composition according to any one of the above 1. to 7., in which the abrasive grains are anionically modified colloidal silica;

9. The polishing composition according to any one of the above 1. to 8., further containing a water-soluble polymer;

10. The polishing composition according to the above 9., in which the water-soluble polymer contains polyvinyl alcohol;

11. The polishing composition according to the above 10, in which the water-soluble polymer further contains a polyoxyalkylene compound;

12. The polishing composition according to the above 11, in which the polyoxyalkylene compound contains at least one of polyethylene glycol or polypropylene glycol;

13. The polishing composition according to any one of the above 1. to 12., further containing a dispersing medium;

14. The polishing composition according to any one of the above 1. to 13., which is used for polishing an object to be polished containing silicon oxide;

15. A polishing method including: polishing an object to be polished containing silicon oxide by using the polishing composition according to any one of the above 1. to 14., and

16. A method for manufacturing a semiconductor substrate, the method including: polishing a semiconductor substrate containing silicon oxide by the polishing method according to the above 15.

### EXAMPLES

The present disclosure will be described in more detail with reference to the following Examples and Comparative Examples. However, the technical scope of the present disclosure is not limited only to the following examples. Unless otherwise specified, “%” and “part” mean “% by mass” and “part by mass”, respectively. In addition, in the following Examples, unless otherwise specified, operations were performed under conditions of room temperature (20° C. or higher and 25° C. or lower)/relative humidity of 40% RH or higher and 50% RH or lower. Each physical property was measured as follows.

### <Average Primary Particle Size and Average Secondary Particle Size of Abrasive Grains>

The average primary particle size of the abrasive grains was calculated from the specific surface area of the abrasive grains measured by the BET method using “Flow Sorb II 2300” manufactured by Micromeritics and the density of the abrasive grains. The average secondary particle size of the abrasive grains was measured as the volume average particle size (volume-based arithmetic average diameter; Mv) by a dynamic light scattering particle size/particle size distribution apparatus UPA-UT151 (manufactured by Nikkiso Co., Ltd.).

### <Zeta Potential of Abrasive Grains>

The zeta potential of the abrasive grains in the polishing composition was measured using a zeta potential measuring apparatus (instrument name “ELS-Z2”) manufactured by Otsuka Electronics Co., Ltd.

### <pH of Polishing Composition>

The pH of the polishing composition was measured by a pH meter (manufactured by HORIBA, Ltd., model number: LAQUA).

### <Electrical Conductivity of Polishing Composition>>

The electrical conductivity (EC) of the polishing composition was measured by a tabletop electrical conductivity meter (manufactured by HORIBA, Ltd., model number: DS-71 LAQUA (registered trademark)).

### <Weight Average Molecular Weight (Mw) of Water-Soluble Polymer>

The weight average molecular weight (Mw) of the water-soluble polymer was measured under the following measurement conditions using gel permeation chromatography (GPC):

### (GPC Measurement Conditions)

Measuring apparatus: HLC-8320GPC (manufactured by Tosoh Corporation)
Sample concentration: 0.01% by mass
Column: TSKgel (registered trademark) GMPWXL
Detector: differential refractometer
Eluent: solution of 10 mM lithium bromide dissolved in N,N-dimethylformamide
Flow rate: 1 mL/min
Measurement temperature: 40° C.
Molecular weight conversion: polyethylene glycol conversion
Sample injection volume: 200 μL

### <Manufacturing of Sulfonic Acid-Modified Colloidal Silica>

According to the following procedure, sulfonic acid-modified colloidal silica as abrasive grains was obtained.

### (Step of Preparing Raw Material Colloidal Silica Dispersion (Non-Modified Silica Particles))

In a flask, 4080 g of methanol, 610 g of water, and 168 g of a 29% by mass aqueous ammonia solution were mixed, the liquid temperature was maintained at 20° C., and a mixed liquid of 135 g of methanol and 508 g of tetramethoxysilane (TMOS) was added dropwise thereto for a dropwise addition time of 25 minutes. Thereafter, hot concentrated water substitution was performed under the condition of pH7 or more to obtain 1000 g of a 19.5% by mass silica sol (average primary particle size: 34 nm)

### (Surface Modification Step)

Subsequently, to 1000 g of the silica sol obtained above (195 g in terms of silica solid content), 1.2 g of 3-mercaptopropyltrimethoxysilane (MPS, silane coupling agent, product name: KBM-803, manufactured by Shin-Etsu Chemical Co., Ltd.) (silane coupling agent concentration based on the total mass of silica solid content: 0.6% by mass) separately mixed with 4.8 g of methanol was added dropwise at a flow rate of 1 mL/min. Thereafter, heating was performed, and pure water replacement was performed for 3 hours after boiling.

Next, for cooling, the reaction solution was allowed to stand overnight, 0.0343 g of 30% by mass hydrogen peroxide water (3 mol with respect to 1 mol of the silane coupling agent) was added thereto, and the mixture was boiled again. Thereafter, pure water replacement was performed for 2 hours, followed by cooling to room temperature (25° C.) to obtain sulfonic acid-modified colloidal silica.

### Example 1

### <Preparation of Polishing Composition>

Sulfonic acid-modified colloidal silica (average primary particle size: 34 nm) as abrasive grains manufactured in <Manufacturing of sulfonic acid-modified colloidal silica> described above was added to water as a dispersing medium to have a final concentration of 2% by mass. Furthermore, ammonium sulfate (manufactured by Tokyo Chemical Industry Co., Ltd.) as an inorganic salt was added such that the final concentration becomes 6,000 ppm by mass (0.6% by mass), tetraethylammonium hydroxide (TEAH, manufactured by Tokyo Chemical Industry Co., Ltd.) as an organic onium salt was added such that the final concentration becomes 150 ppm by mass (0.015% by mass), and stirring and mixing were performed (stirring temperature: 25° C., stirring time: 20 minutes). The pH of the polishing composition was adjusted to 2.0 using nitric acid to complete a polishing composition 1.

### Example 2

A polishing composition 2 was prepared in the same manner as in Example 1 except that the addition amount of ammonium sulfate was changed to an amount such that the final concentration was 2,000 ppm by mass (0.2% by mass).

### Example 3

A polishing composition 3 was prepared in the same manner as in Example 1 except that the addition amount of ammonium sulfate was changed to an amount such that the final concentration was 100 ppm by mass (0.01% by mass).

### Example 4

A polishing composition 4 was prepared in the same manner as in Example 1 except that the addition amount of ammonium sulfate was changed to an amount such that the final concentration was 9,000 ppm by mass (0.9% by mass).

### Example 5

A polishing composition 5 was prepared in the same manner as in Example 1 except that tetra n-butylammonium hydroxide (TBAH, manufactured by Tokyo Chemical Industry Co., Ltd.) was used instead of tetraethylammonium hydroxide.

### Example 6

A polishing composition 6 was prepared in the same manner as in Example 1 except that the pH of the polishing composition was adjusted to 4.0 using nitric acid.

### Example 7

A polishing composition 7 was prepared in the same manner as in Example 1 except that the pH of the polishing composition was adjusted to 7.0 using nitric acid.

### Comparative Example 1

A comparative polishing composition 1 was prepared in the same manner as in Example 1 except that ammonium sulfate and tetraethylammonium hydroxide were not used.

### Comparative Example 2

A comparative polishing composition 2 was prepared in the same manner as in Example 1 except that tetraethylammonium hydroxide was not used.

### Comparative Example 3

A comparative polishing composition 3 was prepared in the same manner as in Example 1 except that ammonium sulfate was not used.

### Comparative Example 4

A comparative polishing composition 4 was prepared in the same manner as in Example 1 except that stearyltrimethylammonium chloride (manufactured by Tokyo Chemical Industry Co., Ltd.) was used instead of tetraethylammonium hydroxide.

The configurations of the polishing compositions of Examples 1 to 7 and Comparative Examples 1 to 4 are shown in Table 1 below. In Table 1 below, “-” indicates that the component is not used.

TABLE 1

| | | Abrasive grains | | | | | | | | | | |
|---|---|---|---|---|---|---|---|---|---|---|---|---|
| | | | Average | Average | | Inorganic salt | | Organic onium salt | | | | |
| | | Concen- | primary | secondary | | | Concen- | | Concen- | | | |
| | Polishing | tration | particle | particle | Zeta | | tration | | tration | Polishing composition | | |
| | composition | (% by | size | size | potential | | (ppm by | | (ppm by | pH adjusting | | EC |
| | No. | mass) | (nm) | (nm) | (mV) | Type | mass) | Type | mass) | agent | pH | (mS/cm) |
| Example 1 | 1 | 2 | 34 | 70 | −25 | Ammonium | 6000 | TEAH | 150 | Nitric acid | 2.0 | 14 |
| | | | | | | sulfate | | | | | | |
| Example 2 | 2 | 2 | 34 | 70 | −25 | Ammonium | 2000 | TEAH | 150 | Nitric acid | 2.0 | 10 |
| | | | | | | sulfate | | | | | | |
| Example 3 | 3 | 2 | 34 | 70 | −25 | Ammonium | 100 | TEAH | 150 | Nitric acid | 2.0 | 8 |
| | | | | | | sulfate | | | | | | |
| Example 4 | 4 | 2 | 34 | 70 | −25 | Ammonium | 9000 | TEAH | 150 | Nitric acid | 2.0 | 17 |
| | | | | | | sulfate | | | | | | |
| Example 5 | 5 | 2 | 34 | 70 | −25 | Ammonium | 6000 | TBAH | 150 | Nitric acid | 2.0 | 14 |
| | | | | | | sulfate | | | | | | |
| Example 6 | 6 | 2 | 34 | 70 | −25 | Ammonium | 6000 | TEAH | 150 | Nitric acid | 4.0 | 8 |
| | | | | | | sulfate | | | | | | |
| Example 7 | 7 | 2 | 34 | 70 | −30 | Ammonium | 6000 | TEAH | 150 | Nitric acid | 7.0 | 3 |
| | | | | | | sulfate | | | | | | |
| Comparative | Comparative | 2 | 34 | 70 | −40 | — | — | — | — | Nitric acid | 2.0 | 6 |
| Example 1 | 1 | | | | | | | | | | | |
| Comparative | Comparative | 2 | 34 | 70 | −35 | Ammonium | 6000 | — | — | Nitric acid | 2.0 | 14 |
| Example 2 | 2 | | | | | sulfate | | | | | | |
| Comparative | Comparative | 2 | 34 | 70 | −40 | — | — | TEAH | 150 | Nitric acid | 2.0 | 6 |
| Example 3 | 3 | | | | | | | | | | | |
| Comparative | Comparative | 2 | 34 | 70 | −40 | Ammonium | 6000 | Stearyl- | 150 | Nitric acid | 2.0 | 14 |
| Example 4 | 4 | | | | | sulfate | | trimethyl- | | | | |
| | | | | | | | | ammonium | | | | |
| | | | | | | | | chloride | | | | |

### Example 8

### <Preparation of Polishing Composition>

Sulfonic acid-modified colloidal silica (average primary particle size: 34 nm) as abrasive grains manufactured in <Manufacturing of sulfonic acid-modified colloidal silica> described above was added to water as a dispersing medium to have a final concentration of 4% by mass. Furthermore, ammonium sulfate (manufactured by Tokyo Chemical Industry Co., Ltd.) as an inorganic salt was added to have a final concentration of 2,000 ppm by mass (0.2% by mass), tetraethylammonium hydroxide (TEAH, manufactured by Tokyo Chemical Industry Co., Ltd.) as an organic onium salt was added to have a final concentration of 26 ppm by mass (0.0026% by mass), and stirring and mixing were performed (stirring temperature: 25° C., stirring time: 20 minutes). The pH of the polishing composition was adjusted to 2.1 using nitric acid to complete a polishing composition 8.

### Example 9

A polishing composition 9 was prepared in the same manner as in Example 8 except that polyvinyl alcohol (PVA, weight average molecular weight: 10,000) was further added to have a final concentration of 1,000 ppm by mass (0.1% by mass).

### Example 10

A polishing composition 10 was prepared in the same manner as in Example 8 except that polyvinyl alcohol (PVA, weight average molecular weight: 10,000) was further added such that the final concentration becomes 1,000 ppm by mass (0.1% by mass), and polyethylene glycol (PEG, weight average molecular weight: 200) was further added such that the final concentration becomes 3,000 ppm by mass (0.3% by mass).

### Example 11

A polishing composition 11 was prepared in the same manner as in Example 8 except that polyvinyl alcohol (PVA, weight average molecular weight: 10,000) was further added such that the final concentration becomes 1,000 ppm by mass (0.1% by mass), and polypropylene glycol (PPG, weight average molecular weight: 400) was further added such that the final concentration becomes 600 ppm by mass (0.06% by mass).

### Comparative Example 5

A comparative polishing composition 5 was prepared in the same manner as in Example 8 except that tetraethylammonium hydroxide (TEAH) was not used.

The configurations of the polishing compositions of Examples 8 to 11 and Comparative Example 5 are shown in Table 2 below. In Table 2 below, “-” indicates that the component is not used.

TABLE 2

| | | | | | | Inorganic | | Organic | |
|---|---|---|---|---|---|---|---|---|---|
| | | Abrasive grains | | | | salt | | onium salt | |
| | | Concen- | Average | Average | | | Concen- | | Concen- |
| | | tration | primary | secondary | Zeta | | tration | | tration |
| | | (% by | particle | particle | potential | | (ppm by | | (ppm by |
| | No. | mass) | size (nm) | size (nm) | (mV) | Type | mass) | Type | mass) |
| Example 8 | 8 | 4 | 34 | 70 | −25 | Ammonium | 2000 | TEAH | 26 |
| | | | | | | sulfate | | | |
| Example 9 | 9 | 4 | 34 | 70 | −25 | Ammonium | 2000 | TEAH | 26 |
| | | | | | | sulfate | | | |
| Example 10 | 10 | 4 | 34 | 70 | −25 | Ammonium | 2000 | TEAH | 26 |
| | | | | | | sulfate | | | |
| Example 11 | 11 | 4 | 34 | 70 | −25 | Ammonium | 2000 | TEAH | 26 |
| | | | | | | sulfate | | | |
| Comparative | Comparative | 4 | 34 | 70 | −25 | Ammonium | 2000 | — | — |
| Example 5 | 5 | | | | | sulfate | | | |

| | Water-soluble | | | Polyoxyalkylene | | | | | |
|---|---|---|---|---|---|---|---|---|---|
| | polymer | | | compound | | | Polishing | | |
| | | | Concen- | | | Concen- | composition | | |
| | | | tration | | | tration | pH | | |
| | | | (ppm by | | | (ppm by | adjusting | | EC |
| | Type | Mw | mass) | Type | Mw | mass) | agent | pH | (mS/cm) |
| Example 8 | — | — | — | — | — | — | Nitric acid | 2.1 | 7 |
| Example 9 | PVA | 10000 | 1000 | — | — | — | Nitric acid | 2.1 | 7 |
| Example 10 | PVA | 10000 | 1000 | PEG | 200 | 3000 | Nitric acid | 2.1 | 7 |
| Example 11 | PVA | 10000 | 1000 | PPG | 400 | 600 | Nitric acid | 2.1 | 7 |
| Comparative | — | — | — | — | — | — | Nitric acid | 2.1 | 7 |
| Example 5 | | | | | | | | | |

### Evaluation

The following (1) and (2) were prepared as objects to be polished, and polishing was performed under the following conditions:
(1) Silicon nitride film (Si₃N₄ film): a silicon wafer having a silicon nitride film (Si₃N₄ film) with a thickness of 2,000 Å formed on a surface thereof (200 mm, blanket wafer)
(2) Silicon oxide film (TEOS film): a silicon wafer having a TEOS type silicon oxide (SiO₂) film with a thickness of 10,000 Å formed on a surface thereof (200 mm, blanket wafer)

### (Polishing Apparatus and Polishing Conditions)

Polishing apparatus: CMP single-side polishing apparatus for 200 mm, manufactured by Applied Materials Inc., Mirra
Polishing pad: rigid polyurethane pad IC1010 manufactured by NITTA DuPont, Inc.
Polishing pressure: 2.5 psi (1 psi=6894.76 Pa)
Rotation speed of polishing table: 47 rpm
Rotation speed of head (carrier): 43 rpm
Supply of polishing composition: continuous flow
Polishing composition supply amount: 200 mL/min
Polishing time: 60 seconds

### <Polishing Removal Rate>

For each object to be polished, the thickness before and after polishing was determined with an optical film thickness measuring instrument (ASET-f5x: manufactured by KLA-Tencor Corporation). The film thickness was determined by an optical film thickness measuring instrument (ASET-f5x: manufactured by KLA-Tencor Corporation).

In each object to be polished, the polishing removal rate in each object to be polished was calculated by dividing the difference in film thickness before and after polishing [(thickness before polishing)−(thickness after polishing)] by the polishing time.

### <Number of Scratches>

The number of scratches on the surface of the silicon oxide film after polishing was measured by measuring coordinates of the entire surface of both surfaces of the object to be polished (excluding the outer circumference of 2 mm) using a wafer inspection apparatus “Surfscan (registered trademark) SP2” manufactured by KLA-Tencor Corporation and observing all the measured coordinates with Review-SEM (RS-6000, manufactured by Hitachi High-Technologies Corporation). Incidentally, scratches on the substrate surface having a depth of 10 nm or more and less than 100 nm, a width of 100 nm or more and less than 500 nm, and a length of 80 nm or more were counted as scratches. The smaller the number of scratches, the more preferable. The number of scratches is practicably 25 or less, preferably 20 or less, more preferably 15 or less, still more preferably 10 or less, and particularly preferably less than 10.

The evaluation results of the polishing removal rate and the number of scratches are shown in the following Table 3. In Table 3 below, the silicon nitride film is indicated by “Si₃N₄”, and the silicon oxide film is indicated by “SiO₂”.

TABLE 3

| | Polishing removal rate (Å/min) | | Number of scratches |
|---|---|---|---|
| | Si₃N₄ | SiO₂ | (pieces) |
| Example 1 | 645 | 322 | 8 |
| Example 2 | 658 | 239 | 9 |
| Example 3 | 677 | 193 | 13 |
| Example 4 | 615 | 354 | 8 |
| Example 5 | 589 | 312 | 10 |
| Example 6 | 534 | 267 | 10 |
| Example 7 | 43 | 178 | 15 |
| Example 8 | 793 | 388 | 9 |
| Example 9 | 788 | 380 | 6 |
| Example 10 | 785 | 375 | 4 |
| Example 11 | 772 | 371 | 5 |
| Comparative | 662 | 150 | 60 |
| Example 1 | | | |
| Comparative | 642 | 316 | 30 |
| Example 2 | | | |
| Comparative | 651 | 152 | 28 |
| Example 3 | | | |
| Comparative | 523 | 352 | 53 |
| Example 4 | | | |
| Comparative | 790 | 385 | 58 |
| Example 5 | | | |

As is apparent from Table 3 above, it was found that scratches on the surface of the silicon oxide film can be reduced in a case where the polishing compositions of Examples were used. On the other hand, it was found that in a case where the polishing compositions of Comparative Examples were used, scratches on the surface of the silicon oxide film increased.

The present application is based on Japanese Patent Application No. 2024-036949 filed on Mar. 11, 2024 and Japanese Patent Application No. 2024-157358 filed on Sep. 11, 2024, the disclosures of which are incorporated herein by reference in their entirety.

What is claimed is:

1. A polishing composition comprising:
abrasive grains;
an inorganic salt; and
an organic onium salt, wherein
the organic onium salt contains at least one of a tetraalkylammonium salt represented by Chemical Formula 1 below or a tetraalkylphosphonium salt represented by Chemical Formula 2 below, and
a zeta potential of the abrasive grains in the polishing composition is negative: 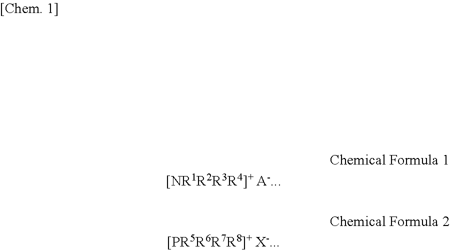
in the Chemical Formula 1 and the Chemical Formula 2,
R¹ to R⁸ each independently represent an unsubstituted alkyl group having 1 or more and 4 or less carbon atoms, and
A⁻ and X⁻ each independently represent a monovalent anion.

2. The polishing composition according to claim 1, wherein the inorganic salt comprises at least one selected from the group consisting of ammonium sulfate, ammonium nitrate, ammonium carbonate, potassium sulfate, potassium nitrate, or potassium carbonate.

3. The polishing composition according to claim 1, wherein the organic onium salt is a tetraalkylammonium salt represented by the Chemical Formula 1.

4. The polishing composition according to claim 1, wherein A⁻ and X⁻ in the Chemical Formula 1 and the Chemical Formula 2 are hydroxide ions.

5. The polishing composition according to claim 1, wherein the tetraalkylammonium salt represented by the Chemical Formula 1 comprises at least one selected from the group consisting of tetraethylammonium hydroxide, tetrapropylammonium hydroxide, or tetra n-butylammonium hydroxide.

6. The polishing composition according to claim 1, wherein a concentration of the organic onium salt with respect to a total mass of the polishing composition is 0.001% by mass or more and 0.01% by mass or less.

7. The polishing composition according to claim 1, wherein pH is less than 7.0.

8. The polishing composition according to claim 1, wherein the abrasive grains are anionically modified colloidal silica.

9. The polishing composition according to claim 1, further comprising a water-soluble polymer.

10. The polishing composition according to claim 9, wherein the water-soluble polymer comprises polyvinyl alcohol.

11. The polishing composition according to claim 10, wherein the water-soluble polymer further comprises a polyoxyalkylene compound.

12. The polishing composition according to claim 11, wherein the polyoxyalkylene compound comprises at least one of polyethylene glycol or polypropylene glycol.

13. The polishing composition according to claim 1, further comprising a dispersing medium.

14. The polishing composition according to claim 1, which is used for polishing an object to be polished containing silicon oxide.

15. A polishing method comprising: polishing an object to be polished containing silicon oxide by using the polishing composition according to claim 1.

16. A method for manufacturing a semiconductor substrate, the method comprising:
polishing a semiconductor substrate containing silicon oxide by the polishing method according to claim 15.
